(19) United States
(12) Patent Application Publication
(10) Pub. No.: US 2023/0408200 A1
(43) Pub. Date: Dec. 21, 2023

(54) COOLING MODULE FOR BAKING DEVICE AND SUBSTRATE TREATING APPARATUS INCLUDING THE SAME

(71) Applicant: SEMES CO., LTD., Chungcheongnam-do (KR)

(72) Inventors: Ju Mi LEE, Seoul (KR); Gyeong Won SONG, Chungcheongnam-do (KR); Min Hee CHO, Gyeonggi-do (KR); Byung Hwi KIM, Gyeonggi-do (KR); Chun Woo PARK, Gyeonggi-do (KR); Hee Man AHN, Seoul (KR)

(21) Appl. No.: 18/143,273

(22) Filed: May 4, 2023

(30) Foreign Application Priority Data
Jun. 15, 2022 (KR) 10-2022-0072717

(51) Int. Cl. F27D 9/00; G03F 7/40

(52) U.S. Cl. CPC F27D 9/00; G03F 7/40; F27D 2009/0078

(57) ABSTRACT

The substrate processing apparatus of the present invention comprises a hot plate for heating a substrate; and a cooling unit for cooling the hot plate; wherein the cooling unit includes a support plate having a space formed between the support plate and the hot plate, and a plurality of nozzles installed on the support plate and for supplying cooling gas to a bottom surface of the hot plate, wherein an outdoor air inlet passage provided in a through structure is provide in the support plate, wherein a portion of the outdoor air inlet passage forms a first region, through which a cable passes, and the remaining portion forms a second region, through which the cable does not pass and outdoor air introduces.

This application claims the benefit of Korean Patent Application No. 10-2022-0072717, filed on Jun. 15, 2022, in the Korean Intellectual Property Office, the disclosure of which is incorporated herein by reference in its entirety.

### BACKGROUND

### 1. Field

The present invention relates to a cooling module for a substrate baking apparatus and a substrate processing apparatus including the same.

### 2. Description of the Related Art

A photolithography process among semiconductor manufacturing processes is a process of forming a desired pattern on a wafer. The photolithography process comprises a photoresist coating process, an exposure process, a baking process, and a developing process.

Here, the baking process is a process of heat-treating a substrate disposed on a hot plate. However, when heat treatment is performed on the substrate, the process temperature may be different. For example, the process temperature may have a difference of 10° C. or more, such as 200° C. and 150° C., and the temperature of the hot plate needs to be rapidly lowered in order to shorten the process time, unlike controlling the fine temperature.

### SUMMARY

On the other hand, cooling gas is used to rapidly lower the temperature of the hot plate, the cooling gas is injected from the nozzle, and efforts to improve the cooling efficiency are continuing.

An object of the present invention is to provide a cooling module for a substrate baking apparatus capable of improving cooling efficiency, and a substrate processing apparatus including the same.

The objects of the present invention are not limited to the objects mentioned above, and other objects not mentioned will be clearly understood by those skilled in the art from the following description.

One aspect of the substrate processing apparatus of the present invention for achieving the above other object comprises a hot plate for heating a substrate; and a cooling unit for cooling the hot plate; wherein the cooling unit includes a support plate having a space formed between the support plate and the hot plate, and a plurality of nozzles installed on the support plate and for supplying cooling gas to a bottom surface of the hot plate, wherein an outdoor air inlet passage provided in a through structure is provide in the support plate, wherein a portion of the outdoor air inlet passage forms a first region, through which a cable passes, and the remaining portion forms a second region, through which the cable does not pass and outdoor air introduces.

Wherein the outdoor air inlet passage is located outside the plurality of nozzles.

Wherein a diameter of the outdoor air inlet passage is formed to be greater than a diameter of the cable so that the first region and the second region are formed together as a single hole, and outdoor air introduces between the cable and the outdoor air inlet passage.

Wherein the outdoor air inlet passage is provided in any one shape among polygonal, circular and elliptical shapes.

Wherein the outdoor air inlet passage has a cross-sectional area of 4 to 8 times a cross-sectional area of the cable.

Wherein a diameter of the hot plate is 25 mm to 35 mm, and a diameter of the outdoor air inlet passage is 9 mm to 17 mm.

Wherein, when the outdoor air inlet passage is provided in an elliptical shape, a length of a short axis of the outdoor air inlet passage is the same as a diameter of the cable so that the cable is in contact with the outdoor air inlet passage, and a length of a long axis of the outdoor air inlet passage is formed to be greater than the diameter of the cable so that outdoor air introduces between the cable and the outdoor air inlet passage.

Wherein, in the outdoor air inlet passage, one or more long holes provided by a plurality of cables spaced apart from each other in one through structure are provided, or the outdoor air inlet passage is provided in a shape of a ring-shaped band, in which a plurality of cables are provided adjacent to each other in one through structure.

Wherein the outdoor air inlet passage comprises a first passage, through which the cable passes, and a periphery of the cable is in close contact with; and a second passage, through which the cable does not pass and outdoor air introduces, and spaced apart from the first passage.

Wherein, in the support plate, a discharge hole is formed in a center so that outdoor air introduced from the outdoor air inlet passage is discharged passing through the discharge hole.

One aspect of the cooling module for a substrate baking apparatus of the present invention for achieving the above other object comprises a cooling unit for cooling a hot plate for heating a substrate, wherein the cooling unit comprises a support plate having a space formed between the support plate and the hot plate, and a plurality of nozzles installed on the support plate and for supplying cooling gas to a bottom surface of the hot plate, wherein an outdoor air inlet passage provided in a through structure in the support plate and located outside the plurality of nozzles is provided, wherein a portion of the outdoor air inlet passage forms a first region, through which a cable passes, and the remaining portion forms a second region, through which the cable does not pass and the outdoor air introduces.

Wherein the outdoor air inlet passage is provided in any one shape among polygonal, circular and elliptical shapes, and has a cross-sectional area of 4 to 8 times a cross-sectional area of the cable.

Wherein a diameter of the outdoor air inlet passage is formed to be greater than a diameter of the cable so that the first region and the second region are formed together as a single hole, and outdoor air introduces between the cable and the outdoor air inlet passage.

Wherein, in the outdoor air inlet passage, one or more long holes provided by a plurality of cables spaced apart from each other in one through structure are provided, or the outdoor air inlet passage is provided in a shape of a ring-shaped band, in which a plurality of cables are provided adjacent to each other in one through structure.

Wherein the second region has a cross-sectional area of 10 to 15 times a cross-sectional area of the first region.

One aspect of the cooling module for a substrate baking apparatus of the present invention for achieving the above another object comprises a cooling unit for cooling a hot plate for heating a substrate, wherein the cooling unit comprises a support plate having a space formed between the support plate and the hot plate and a discharge hole formed in a center, and a plurality of nozzles installed on the support plate and for supplying a cooling gas to a bottom surface of the hot plate, and disposed adjacent to a periphery with respect to a center of the support plate, wherein the cooling gas is discharged in an oblique direction toward a center of the hot plate with respect to a periphery of the hot plate, wherein an outdoor air inlet passage provided in a through structure in the support plate, and located outside the plurality of nozzles is provided, wherein a portion of the outdoor air inlet passage forms a first region, through which the cable passes, and the remaining portion forms a second region, through which the cable does not pass and outdoor air introduces.

Wherein the outdoor air inlet passage is provided in any one shape among polygonal, circular and elliptical shapes and has a cross-sectional area of 4 to 8 times a cross-sectional area of the cable, and a cooling gas supplied from the plurality of nozzles has a discharge flow rate of 80 lpm or more so that a negative pressure is formed outside the nozzle, and has a discharge flow rate of 180 lpm or less so that a particle is not generated under the hot plate, and a discharge flow rate of the cooling gas is between 80 lpm to 180 lpm.

Wherein a diameter of the outdoor air inlet passage is 9 mm to 17 mm.

Wherein, in the outdoor air inlet passage, one or more long holes provided by a plurality of cables spaced apart from each other in one through structure are provided, or the outdoor air inlet passage is provided in a shape of a ring-shaped band, in which a plurality of cables are provided adjacent to each other in one through structure.

Wherein a diameter of the outdoor air inlet passage is 9 mm to 17 mm.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram illustrating a substrate processing apparatus according to some embodiments of the present invention;

FIG. 2 is a plan view showing a cooling unit according to a first embodiment of the present invention;

FIG. 3 is a plan view illustrating a state, in which a cable is disposed in the outdoor air inlet passage of the cooling unit according to the first embodiment of the present invention;

FIG. 4 is a plan view illustrating a state, in which a cable is disposed in an outdoor air inlet passage of a cooling unit according to a second embodiment of the present invention;

FIG. 5 is a plan view illustrating a state, in which a cable is disposed in an outdoor air inlet passage of a cooling unit according to a third embodiment of the present invention;

FIG. 6 is a plan view illustrating a state, in which a cable is disposed in an outdoor air inlet passage of a cooling unit according to a fourth embodiment of the present invention;

FIG. 7 is a plan view illustrating a state, in which a cable is disposed in an outdoor air inlet passage of a cooling unit according to a fifth embodiment of the present invention;

FIG. 8 is a plan view illustrating a cooling unit according to a sixth embodiment of the present invention;

FIG. 9 is a diagram illustrating a fluid flow in a substrate processing apparatus according to some embodiments of the present disclosure; and

FIG. 10 is a diagram illustrating a cooling capacity according to a diameter of an outdoor air inlet passage of a substrate processing apparatus according to some embodiments of the present disclosure.

### DETAILED DESCRIPTION

Hereinafter, preferred embodiments of the present invention will be described in detail with reference to the accompanying drawings. Advantages and features of the present invention and methods of achieving them will become apparent with reference to the embodiments described below in detail in conjunction with the accompanying drawings. However, the present invention is not limited to the embodiments described below, but may be implemented in various different forms, and these embodiments are provided to make the description of the present invention complete, and fully inform those skilled in the art, to which the present invention pertains on the scope of the invention, and the present invention is only defined by the scope of the claims. Like reference numerals refer to like elements throughout.

The terminology used herein is for the purpose of describing the embodiments and is not intended to limit the present invention. In this specification, the singular also includes the plural, unless specifically stated otherwise in the phrase. As used herein, “comprises” and/or “comprising” means that components, steps, operations and/or elements mentioned does not exclude the presence or the addition of one or more other components, steps, operations and/or elements.

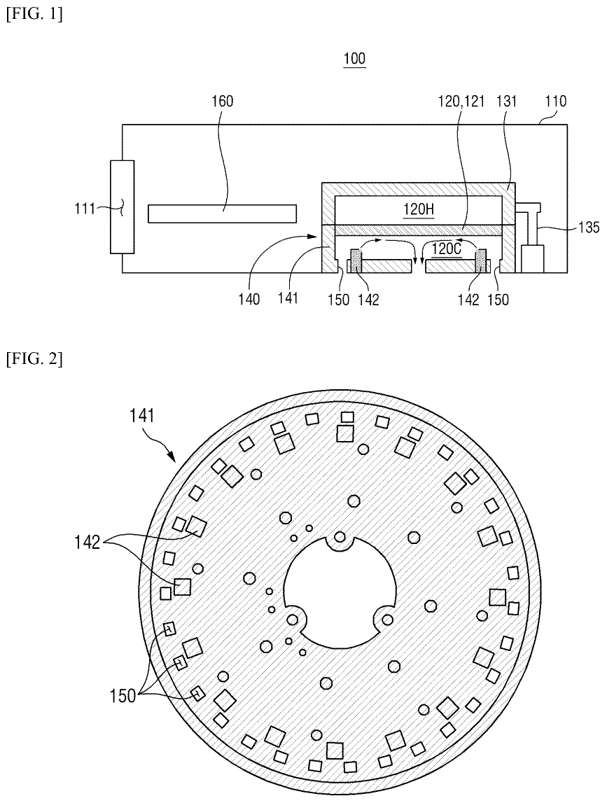

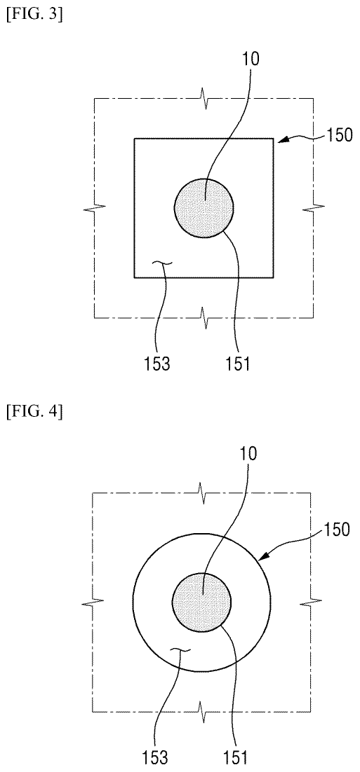

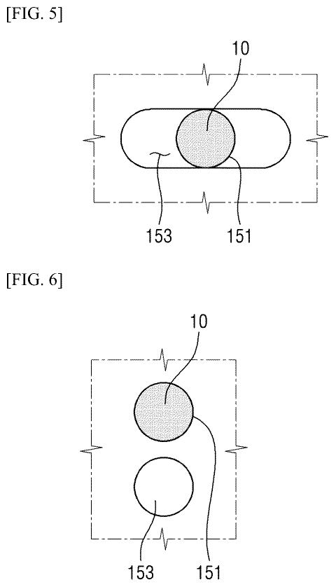

FIG. 1 is a diagram illustrating a substrate processing apparatus according to some embodiments of the present invention, FIG. 2 is a plan view illustrating a cooling unit according to a first embodiment of the present invention, and FIG. 3 is a plan view showing a state, in which the cable is disposed in the outdoor air inlet passage of the cooling unit according to a first embodiment of the present invention. And, FIGS. 4 and 5 are plan views showing a state, in which the cable is disposed in the outdoor air inlet passage of the cooling unit according to the second and third embodiments of the present invention.

Referring to FIGS. 1 to 5, the substrate processing apparatus 100 according to an embodiment of the present invention may include a housing 110, a heating unit 120, a cooling unit 140, and a cooling plate 160.

The substrate processing apparatus 100 of the present embodiment may perform a baking process. For example, the substrate processing apparatus 100 may perform a pre-baking process of heating the substrate to a predetermined temperature to remove organic matter or moisture from the surface of the substrate before applying the photoresist to the substrate. Alternatively, the substrate processing apparatus 100 may perform a soft bake process of heating the substrate to a predetermined temperature after applying the photoresist to the substrate. However, since this is only an example, the present invention is not limited thereto.

In addition, FIG. 1 disclosed in this embodiment is conceptually illustrated for convenience of understanding and description, and when the cooling gas is supplied to the hot plate 121, the cover 131 may be spaced apart from the hot plate 121.

The housing 110 may have a space formed therein. An entrance 111 through which the substrate is brought into or discharged from the inner space of the housing 110 may be formed on one wall of the housing 110.

The entrance 111 may be in an open state, and according to a modification of the embodiment, a door may be provided to open and close. The inside of the housing 110 may be at atmospheric pressure as the entrance 111 is in an open state, and outdoor air may flow in and out.

A heating unit 120, a cooling unit 140, and a cooling plate 160 may be provided inside the housing 110.

The heating unit 120 is a component to heat the substrate, and may be configured to heat the substrate to a predetermined temperature. The heating unit 120 may be provided with a hot plate 121.

The hot plate 121 is a component that transfers heat to the substrate, and the substrate may be disposed on the upper surface. The hot plate 121 may have a heating member (not shown) therein to apply heat to the substrate. Exemplarily, the heating member may include a heating wire, an electric heating coil, or a heating pattern.

The hot plate 121 may be installed on an inner upper portion of the support plate 141. However, a gap may be formed between the hot plate 121 and the support plate 141 due to a design error or an assembly error.

Although outdoor air may be introduced through the gap between the hot plate 121 and the support plate 141, the hot plate 121 may preferably have a circular plate shape so that the temperature of the hot plate 121 is uniformly formed while the hot plate 121 is stably fixed to the support plate 141.

In other words, when a specific region is deleted or protruded along the outer periphery to fix the hot plate 121, heat or cold provided from the heating member or cooling gas is difficult to be uniformly formed in terms of temperature distribution according to the cross-sectional area difference of the specific region of the hot plate 121, or a waiting time for the entire surface of the hot plate 121 to be uniform in temperature may occur. This is because, in the process of generating a temperature change of 10 degrees or more, if the cross-sectional area of a specific region is larger than that of another region, more energy is required to increase or decrease the temperature by the added area.

However, in the present embodiment, the cooling efficiency can be improved without causing a change in shape around the hot plate 121 while improving the cooling efficiency by utilizing the outdoor air. In other words, by changing the structure of the cooling unit 140 so as not to adversely affect the temperature control of the hot plate 121, the cooling efficiency can be improved, and the temperature of the hot plate 121 can be uniformly controlled in a short time. This will be described in the outdoor air inlet passage 150 to be described later.

A cover 131 may be provided on the hot plate 121. The cover 131 may have a cylindrical shape with an open bottom. The cover 131 is movable up and down, and may cover the hot plate 121 or be spaced apart from the hot plate 121 depending on the position.

That is, between the cover 131 and the hot plate 121, a heating space 120H, in which a heat treatment process of the substrate is performed, may be formed. The cover 131 may move upward with respect to the support plate 141 so that the substrate is loaded into the heating space 120H, or move downward to contact the support plate 141 to close the heating space 120H. According to a modification of the embodiment, a sealing member (not shown) may be provided between the cover 131 and the support plate 141.

For elevating the cover 131, a cover elevating device 135 may be provided adjacent to the cover 131. The cover elevating device 135 may be configured to elevate the cover 131. For example, the cover elevating device 135 may include an actuator using pneumatic or hydraulic pressure, a linear motor operated by electromagnetic interaction, or a ball screw mechanism, but this is only an example.

The cooling unit 140 is a cooling module for a substrate baking apparatus, and may cool the hot plate 121. This is to cool the hot plate 121 to adjust the temperature of the hot plate 121 because the process temperature provided to the substrate is different depending on the baking process. For example, the cooling gas may be supplied to the cooling space 120C so that the temperature of the hot plate 121 rapidly drops from 200° C. to 150° C. In other words, the cooling unit 140 is not provided to finely adjust the temperature of the hot plate 121, but may be provided to rapidly lower the temperature to a temperature difference of 10° C. or more in a short time such as 2 minutes or less.

The cooling unit 140 may include a support plate 141 and a plurality of nozzles 142, and an outdoor air inlet passage 150 provided in a through structure in the support plate 141 may be provided.

Specifically, the support plate 141 may have a cooling space 120C formed between the support plate 141 and the hot plate 121 so that the cooling gas may pass through the lower portion of the hot plate 121. In addition, a structure, in which the cover 131 is disposed on the support plate 141, is provided so that the cover 131 is covered on the support plate 141 to close the heating space 120H formed in the upper portion of the hot plate 121.

The support plate 141 may be provided with a hot plate 121. For example, the hot plate 121 may be installed on the inner circumferential surface of the support plate 141 so that the cover 131 abuts against the support plate 141 to close the heating space 120H.

The shape of the support plate 141 may have a structure concave from the top to the bottom, and may have a structure, in which a peripheral wall is formed. That is, the support plate 141 may have a cylindrical shape with an open top, and the support plate 141 and the cover 131 may have a vertically symmetrical structure. However, such as a cable 10 for supplying electricity to the heating member may be installed in the support plate 141, and a discharge hole (reference numeral not shown) may be formed in the center thereof, there is a difference in some structures. Here, the discharge hole may discharge outdoor air and cooling gas introduced from the outdoor air inlet passage 150.

The plurality of nozzles 142 may supply cooling gas to the bottom surface of the hot plate 121. The plurality of nozzles 142 may be installed on the support plate 141. However, such as the nozzle 142 may have a hole structure and have a structure penetrating through the support plate 141, the installation of the nozzle 142 referred to herein may mean processing a hole or providing a hole.

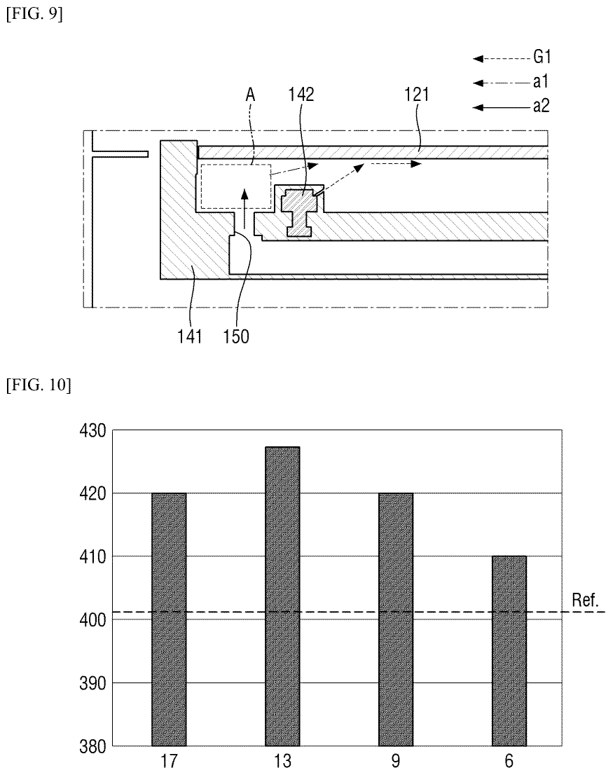

The nozzle 142 may be disposed adjacent to the peripheral of the hot plate 121 with respect to the center (see FIGS. 1 and 2). The nozzles 142 may be spaced apart from each other along an arc smaller than the diameter of the hot plate 121. The outlet of the nozzle 142 may be formed in an oblique direction toward the center of the hot plate 121 (see FIG. 9). Accordingly, the cooling gas supplied from the nozzle 142 may move along the bottom surface of the hot plate 121 and then be discharged through the discharge hole of the support plate 141 located on the same central axis as the center of the hot plate 121.

And the cooling gas may be discharged at a predetermined discharge pressure or discharge flow rate through the nozzle 142 so that a negative pressure is formed between the inner peripheral wall of the support plate 141 and the nozzle 142 (see ‘A’ in FIG. 9).

The discharge pressure or discharge flow rate of the cooling gas is a condition for providing a negative pressure around the nozzle 142, for example, the discharge flow rate of the cooling gas may be between 80 lpm (liters per minute) to 180 lpm. This is for the cooling gas to have a flow rate of 80 lpm or more to form a negative pressure, but to have a discharge flow rate of 180 lpm or less so that particles are not generated due to damage to the hot plate 121 due to the discharge pressure. In addition, if a plurality of baking devices (e.g., 10) are provided inside the substrate processing apparatus and the discharge flow rate is excessive, a load may be generated in the supply module for supplying the cooling gas, and there is a risk that the cooling gas may not be uniformly distributed. Therefore, to prevent this, the cooling gas may be supplied at a discharge flow rate between 100 lpm and 150 lpm.

When the flow rate of the cooling gas is formed as 80 lpm (liters per minute) to 180 lpm, and the outdoor air flows into the cooling space 120C from the outside at atmospheric pressure, since the outdoor air having a low temperature compared to the temperature of the hot plate 121 can be utilized, cooling efficiency can be improved. In other words, outdoor air is forcibly introduced through the second region 153 from the outside, and a cooling action using the outdoor air may be achieved.

Specifically, the outdoor air inlet passage 150 is a configuration, in which the cable 10 may be installed and the outdoor air is introduced, and may be provided in a through structure in the support plate 141.

The outdoor air inlet passage 150 may be located outside the plurality of nozzles 142 in the support plate 141 so that outdoor air can be forcibly introduced from the outside of the nozzle 142 where the negative pressure is formed.

Referring to FIG. 9, when the cooling gas is discharged from the nozzle 142 (‘G1’ refers to the cooling gas flow), the air around the cooling gas is drawn by the fluid viscosity toward the discharge hole in the center of the support plate 141 (see ‘a1’ flow). Therefore, a negative pressure may be formed around the outer periphery of the nozzle 142 (see the ‘A’ mark).

Then, the negative pressure formed between the peripheral wall of the support plate 141 and the nozzle 142 generates a pressure difference from the outside, so that outdoor air may be introduced into the cooling space 120C through the outdoor air inlet passage 150 (see ‘a2’ flow).

In particular, the outdoor air inlet passage 150 is provided outside the nozzle 142 in the support plate 141, so that outdoor air may be supplied from the outer periphery of the nozzle 142 in a vertical direction. Accordingly, the dead zone, in which the cooling action of the hot plate 121 is insignificant, can be minimized, and the cooling action can be more effective.

A portion of such an outdoor air inlet passage 150 forms the first region 151, through which the cable 10 passes, and the remaining portion forms a second region 153, through which the cable 10 does not pass and the outdoor air introduces.

For example, the diameter of the outdoor air inlet passage 150 may be formed to be greater than the diameter of the cable 10 so that the first region 151 and the second region 153 are formed together as a single hole (it may mean the length of the side in the case of a polygon). In other words, the first region 151 and the second region 153 are provided together in one through structure, and the remainder of the first region 151 among the outdoor air inlet passages 150 may form the second region 153. Accordingly, outdoor air may be introduced between the cable 10 and the outdoor air inlet passage 150. In addition, the first region 151 and the second region 153 may be provided through one hole processing without performing a process for processing the through structures of the first region 151 and the second region 153, respectively. Therefore, it may be easy to manufacture.

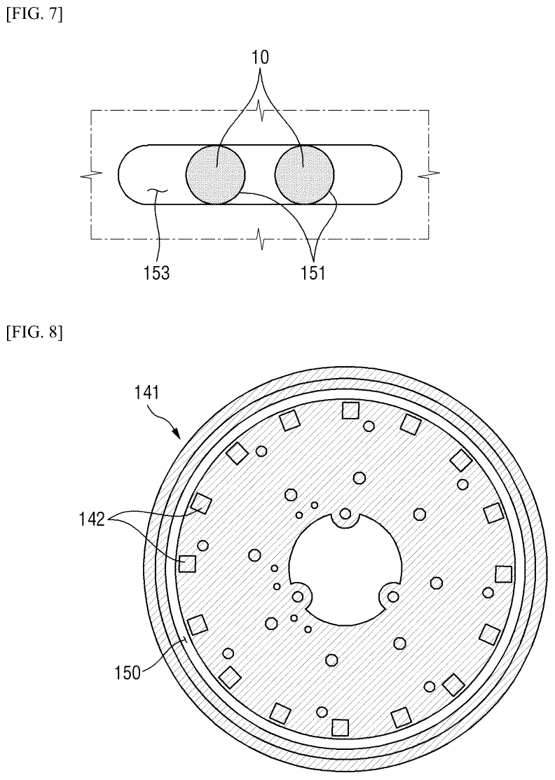

The outdoor air inlet passage 150 may be provided in a polygonal shape (see FIG. 3), a circular shape (see FIG. 4), and an elliptical shape (see FIG. 5). Referring to FIG. 2, although it is illustrated that all of the plurality of outdoor air inlet passages 150 are a polygonal shape (square), but at least one of the plurality of outdoor air inlet passages 150 may be a circular shape, and the rest are provided in a combination of elliptical and polygonal shapes. In addition, the outdoor air inlet passage 150 is not limited that one cable is provided in one through structure. The elliptical shape and the provision of a plurality of cables 10 in one through structure will be described later with reference to FIGS. 7 and 8.

In addition, the outdoor air inlet passage 150 may have a cross-sectional area of 4 to 8 times the cross-sectional area of the cable 10. Preferably, the cross-sectional area of the outdoor air inlet passage 150 may have a cross-sectional area six times that of the cable 10. For example, the cross-sectional area of the cable 10 may be 7.06e⁻⁴ m², and the cross-sectional area of the outdoor air inlet passage 150 may be 44.4e⁻⁴˜15.9e⁻⁴ m².

And, when the diameter of the hot plate 121 is 25 mm to 35 mm, the diameter of the outdoor air inlet passage 150 may be 9 mm to 17 mm. Preferably, the diameter of the outdoor air inlet passage 150 may be 13 mm (however, it may include an error range, and the error range may be 20%).

As shown in FIG. 10 (the experiment is performed by lowering the temperature by from 130° C. to 100° C., the horizontal axis means the diameter of the outdoor air inlet passage 150, and the vertical axis means the cooling capacity (unit, W)), because the cooling capacity is the highest when the diameter of the outdoor air inlet passage 150 is 13 mm.

In addition, the cooling plate 160 may be used so that the temperature of the hot plate 121 of the present embodiment can be cooled more rapidly.

The cooling plate 160 may assist the cooling unit 140 to cool the hot plate 121 together with the cooling unit 140. The cooling plate 160 may have a circular shape that is the same as or similar to the shape of the hot plate 121. A cooling fluid may flow inside the cooling plate 160 according to an embodiment. The cooling plate 160 may transmit cold air from an upper portion of the hot plate 121 opposite to the cooling gas supply.

The cooling plate 160 may be provided at a position deviated from the hot plate 121 when the hot plate 121 provides heat to the substrate. On the other hand, if cooling of the hot plate 121 is required, the cooling plate 160 may be moved to be located above the hot plate 121. However, the cooling plate 160 may transmit cold air to the hot plate 121 in a state, in which a gap is formed between the cooling plate 160 and the hot plate 121 so as not to directly contact the hot plate 121. However, since this is only an example, various modifications are possible.

The substrate processing apparatus 100 according to this embodiment may have an efficient cooling efficiency compared to the comparative example, in which outdoor air is not introduced through the outdoor air inlet passage 150. In other words, since the cooling action region is expanded by the outdoor air inlet passage 150, the heat flux of the hot plate 121, the temperature distribution under the hot plate 121, and the fluid velocity distribution under the hot plate 121 can be all improved. In addition, as the cooling efficiency is improved, the time to reach the target temperature can also be shortened.

Hereinafter, a modified example of the present embodiment will be described with reference to FIGS. 6 to 8, and a redundant description of the same configuration having the same function will be omitted.

FIG. 6 is a plan view illustrating a state, in which a cable is disposed in an outdoor air inlet passage of a cooling unit according to a fourth embodiment of the present invention. With reference to FIG. 6, points different from those described with reference to FIGS. 2 to 5 will be mainly described.

Referring to FIG. 6, the same or similar to the cooling unit 140 of the above-described embodiment, the support plate 141 and a plurality of nozzles 142 may be included, and an outdoor air inlet passage 150 provided in a through structure in the support plate 141 may be provided.

However, the outdoor air inlet passage 150 of the present embodiment may include a first passage and a second passage.

The first passage may correspond to the first region 151. The first passage of this embodiment has a structure separated from the second passage, so that the cable 10 passes through the first passage, but may be in close contact with the periphery of the cable 10.

The second passage may correspond to the second region 153, and the cable does not pass therethrough and outdoor air may be introduced. The second passage may be provided to be separated from the first passage and spaced apart from the first passage.

Hereinafter, another example will be described.

FIG. 7 is a plan view illustrating a state, in which a cable is disposed in an outdoor air inlet passage of a cooling unit according to a fifth embodiment of the present invention, and FIG. 8 is a plan view illustrating a cooling unit according to a sixth embodiment of the present invention. With reference to FIGS. 7 and 8, points different from those described with reference to FIGS. 2 to 6 will be mainly described.

Referring to FIGS. 7 and 8, as the cooling unit 140 of the fifth and sixth embodiments is the same as or similar to the cooling unit 140 of the above-described embodiment, the support plate 141 and a plurality of nozzles 142 may be included and an outdoor air inlet passage 150 provided in a through structure in the support plate 141 may be provided.

On the other hand, as shown in FIG. 7, in the cooling unit 140 of the fifth embodiment, the outdoor air inlet passage 150 is provided with a long hole, and a plurality of cables 10 may be provided to be spaced apart from each other in one through structure. For example, the outdoor air inlet passage 150 may be provided in an elliptical shape. In addition, the elliptical shape may have a shape bent along the arc of the hot plate 121.

When the cooling unit 140 is provided in an elliptical shape, both the length of the long axis and the short axis of the cooling unit 140 may be greater than the diameter of the cable 10. Alternatively, the length of the short axis of the cooling unit 140 may be the same as the diameter of the cable 10 as follows.

In other words, the length of the long axis of the outdoor air inlet passage 150 is formed to be greater than the diameter of the cable 10, so that outdoor air can be introduced between the outdoor air inlet passage 150 and the cable 10. On the other hand, the length of the short axis of the elliptical-shaped outdoor air inlet passage 150 may be the same as the diameter of the cable 10 so that the cable 10 may come into contact with the outdoor air inlet passage 150. Accordingly, the cable 10 may have a form temporarily fixed to the outdoor air inlet passage 150. However, in the cable 10, a plurality of wires may be bundled in a unit, and the end may be fixed to the hot plate 121 even if it is not fixed to the outdoor air inlet passage 150, so that the cable 10 does not need be limited to being fixed to the outdoor air inlet passage 150.

As another example, as shown in FIG. 8, in the cooling unit 140 of the sixth embodiment, the outdoor air inlet passage 150 may be provided in a shape of a ring-shaped band, in which a plurality of cables 10 are provided adjacent to each other in one through structure. In other words, it may be a structure, in which one through structure is provided, and the cable 10 all penetrates through one through structure.

For example, in the band-shaped outdoor air inlet passage 150, the second region 153 may have a cross-sectional area of 10 to 15 times that of the first region 151. In addition, although not shown in the drawings, the outdoor air inlet passage 150 provided in a band shape formed of a single through structure may have various modifications as a pin may be provided for the connection structure.

Although the embodiments of the present invention have been described above with reference to the accompanying drawings, the present invention is not limited to the above embodiments, but may be manufactured in a variety of different forms, and those of ordinary skill in the art to which the present invention pertains can understand that the present invention may be embodied in other specific forms without changing the technical spirit or essential features of the present invention. Therefore, it should be understood that the embodiments described above are illustrative in all respects and not limiting.

### REFERENCE NUMERAL

100: substrate processing apparatus 110: housing
120: heating unit 140: cooling unit
160: cooling plate

What is claimed is:

1. An apparatus for processing a substrate comprising:
a hot plate for heating a substrate; and
a cooling unit for cooling the hot plate;
wherein the cooling unit includes,
a support plate having a space formed between the support plate and the hot plate, and
a plurality of nozzles installed on the support plate and for supplying cooling gas to a bottom surface of the hot plate,
wherein an outdoor air inlet passage provided in a through structure is provide in the support plate,
wherein a portion of the outdoor air inlet passage forms a first region, through which a cable passes, and the remaining portion forms a second region, through which the cable does not pass and outdoor air introduces.

2. The apparatus of claim 1, wherein the outdoor air inlet passage is located outside the plurality of nozzles.

3. The apparatus of claim 1, wherein a diameter of the outdoor air inlet passage is formed to be greater than a diameter of the cable so that the first region and the second region are formed together as a single hole, and outdoor air introduces between the cable and the outdoor air inlet passage.

4. The apparatus of claim 3, wherein the outdoor air inlet passage is provided in any one shape among polygonal, circular and elliptical shapes.

5. The apparatus of claim 4, wherein the outdoor air inlet passage has a cross-sectional area of 4 to 8 times a cross-sectional area of the cable.

6. The apparatus of claim 4, wherein a diameter of the hot plate is 25 mm to 35 mm,
wherein a diameter of the outdoor air inlet passage is 9 mm to 17 mm.

7. The apparatus of claim 4, wherein, when the outdoor air inlet passage is provided in an elliptical shape, a length of a short axis of the outdoor air inlet passage is the same as a diameter of the cable so that the cable is in contact with the outdoor air inlet passage, and a length of a long axis of the outdoor air inlet passage is formed to be greater than the diameter of the cable so that outdoor air introduces between the cable and the outdoor air inlet passage.

8. The apparatus of claim 3, wherein, in the outdoor air inlet passage, one or more long holes provided by a plurality of cables spaced apart from each other in one through structure are provided, or the outdoor air inlet passage is provided in a shape of a ring-shaped band, in which a plurality of cables are provided adjacent to each other in one through structure.

9. The apparatus of claim 1, wherein the outdoor air inlet passage comprises,
a first passage, through which the cable passes, and a periphery of the cable is in close contact with; and
a second passage, through which the cable does not pass and outdoor air introduces, and spaced apart from the first passage.

10. The apparatus of claim 1, wherein, in the support plate, a discharge hole is formed in a center so that outdoor air introduced from the outdoor air inlet passage is discharged through the discharge hole.

11. A cooling module for a substrate baking apparatus comprising:
a cooling unit for cooling a hot plate for heating a substrate,
wherein the cooling unit comprises,
a support plate having a space formed between the support plate and the hot plate, and
a plurality of nozzles installed on the support plate and for supplying cooling gas to a bottom surface of the hot plate,
wherein an outdoor air inlet passage provided in a through structure in the support plate and located outside the plurality of nozzles is provided,
wherein a portion of the outdoor air inlet passage forms a first region, through which a cable passes, and the remaining portion forms a second region, through which the cable does not pass and outdoor air introduces.

12. The cooling module of claim 11, wherein the outdoor air inlet passage is provided in any one shape among polygonal, circular and elliptical shapes, and has a cross-sectional area of 4 to 8 times a cross-sectional area of the cable.

13. The cooling module of claim 12, wherein a diameter of the outdoor air inlet passage is formed to be greater than a diameter of the cable so that the first region and the second region are formed together as a single hole, and outdoor air introduces between the cable and the outdoor air inlet passage.

14. The cooling module of claim 11, wherein, in the outdoor air inlet passage, one or more long holes provided by a plurality of cables spaced apart from each other in one through structure are provided, or the outdoor air inlet passage is provided in a shape of a ring-shaped band, in which a plurality of cables are provided adjacent to each other in one through structure.

15. The cooling module of claim 14, wherein the second region has a cross-sectional area of 10 to 15 times a cross-sectional area of the first region.

16. A cooling module for a substrate baking apparatus comprising:
a cooling unit for cooling a hot plate for heating a substrate,
wherein the cooling unit comprises,
a support plate having a space formed between the support plate and the hot plate and a discharge hole formed in a center, and
a plurality of nozzles installed in the support plate and for supplying a cooling gas to a bottom surface of the hot plate, and disposed adjacent to a periphery with respect to a center of the support plate, wherein the cooling gas is discharged in an oblique direction toward a center of the hot plate with respect to a periphery of the hot plate,
wherein an outdoor air inlet passage provided in a through structure in the support plate, and located outside the plurality of nozzles is provided,
wherein a portion of the outdoor air inlet passage forms a first region, through which the cable passes, and the remaining portion forms a second region, through which the cable does not pass and outdoor air introduces.

17. The cooling module of claim 16, wherein the outdoor air inlet passage is provided in any one shape among polygonal, circular and elliptical shapes and has a cross-sectional area of 4 to 8 times a cross-sectional area of the cable,
wherein a cooling gas supplied from the plurality of nozzles has a discharge flow rate of 80 lpm or more so that a negative pressure is formed outside the nozzle, and has a discharge flow rate of 180 lpm or less so that a particle is not generated under the hot plate, and a discharge flow rate of the cooling gas is between 80 lpm to 180 lpm.

18. The cooling module of claim 16, wherein a diameter of the outdoor air inlet passage is 9 mm to 17 mm.

19. The cooling module of claim 16, wherein, in the outdoor air inlet passage, one or more long holes provided by a plurality of cables spaced apart from each other in one through structure are provided, or the outdoor air inlet passage is provided in a shape of a ring-shaped band, in which a plurality of cables are provided adjacent to each other in one through structure.

20. The cooling module of claim 16, wherein a diameter of the outdoor air inlet passage is 9 mm to 17 mm.
